(19) United States
(12) Patent Application Publication
(10) Pub. No.: US 2025/0183101 A1
(43) Pub. Date: Jun. 5, 2025

(54) EVALUATION APPARATUS, EVALUATION METHOD, AND STORAGE MEDIUM

(71) Applicant: Tokyo Electron Limited, Tokyo (JP)

(72) Inventors: Tsuyoshi MORIYA, Tokyo (JP); Hiroshi NAGAIKE, Miyagi (JP)

(73) Assignee: Tokyo Electron Limited, Tokyo (JP)

(21) Appl. No.: 19/036,581

(22) Filed: Jan. 24, 2025

Related U.S. Application Data
(63) Continuation of application No. PCT/JP2023/026605, filed on Jul. 20, 2023.

(30) Foreign Application Priority Data
Jul. 26, 2022 (JP) 2022-118790

(51) Int. Cl. H01L 21/66; H01L 21/67

(52) U.S. Cl. CPC H01L 22/12; H01L 21/67248; H01L 22/34

(57) ABSTRACT

An evaluation apparatus includes an acquisition unit that acquires data regarding surface temperature distribution of a part that is assembled in a substrate processing apparatus; and an evaluation unit that evaluates an assembly accuracy of the part based on the acquired data regarding the surface temperature distribution of the part.

### CROSS-REFERENCE TO RELATED APPLICATIONS

This application is a continuation application of International Patent Application No. PCT/JP2023/026605, filed on Jul. 20, 2023, which claims priority from Japanese Patent Application No. 2022-118790, filed on Jul. 26, 2022, with the Japan Patent Office, all of which are incorporated herein in their entireties by reference.

### TECHNICAL FIELD

The present disclosure relates to an evaluation apparatus, an evaluation method, and a storage medium.

### BACKGROUND

Various parts are assembled in a semiconductor manufacturing apparatus. When the assembly accuracy of the parts is low, an adverse effect is caused in a process. In the related art, there has been proposed a method for detecting troubles and abnormalities in the apparatuses by performing a semiconductor manufacturing process and evaluating a semiconductor obtained as a product (see, e.g., Japanese Patent Laid-Open Publication No. 2006-310371).

### SUMMARY

An evaluation apparatus according to one aspect of the present disclosure includes an acquisition unit that acquires data regarding surface temperature distribution of a part that is assembled in a substrate processing apparatus; and an evaluation unit that evaluates an assembly accuracy of the part based on the acquired data regarding the surface temperature distribution of the part.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic diagram illustrating a configuration of a semiconductor manufacturing system according to an embodiment of the present disclosure.

FIG. 2A is a schematic diagram illustrating a configuration of main components of a shower head.

FIG. 2B is a schematic diagram illustrating a configuration of the main components of the shower head.

FIG. 3 is a block diagram illustrating an internal configuration of a control device.

FIG. 4 is a schematic diagram illustrating a configuration of a learning model.

FIG. 5 is a flowchart explaining a sequence of processing steps performed by the control device.

FIG. 6 is a schematic diagram illustrating an example of a display when an abnormality is detected.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

The present disclosure will now be described in detail with reference to the drawings illustrating the embodiments thereof.

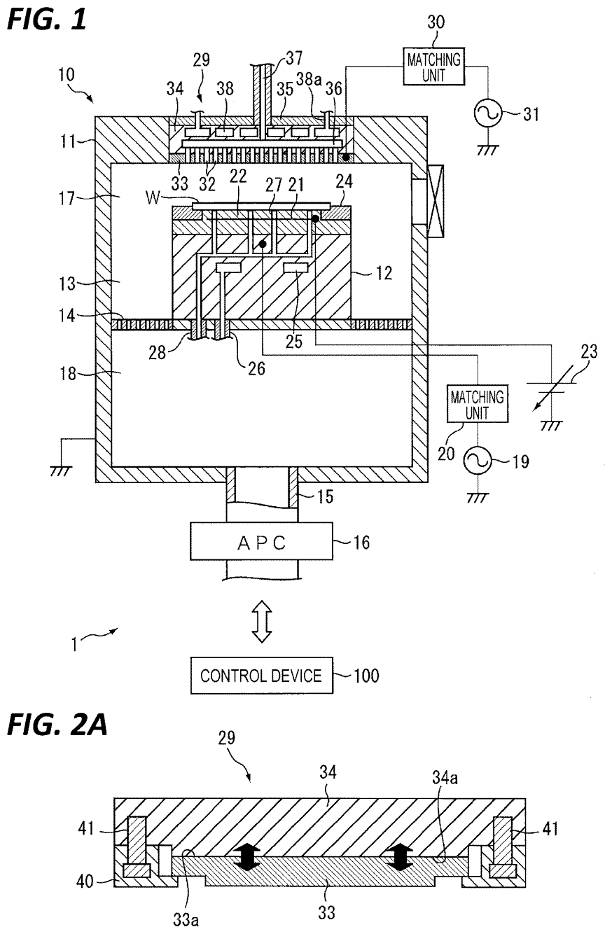

FIG. 1 is a schematic diagram illustrating a configuration of a semiconductor manufacturing system according to an embodiment of the present disclosure. A semiconductor manufacturing system 1 according to the present embodiment includes a semiconductor manufacturing apparatus 10 and a control device 100. The semiconductor manufacturing apparatus 10 is, for example, a plasma processing apparatus that performs a process such as plasma etching on a workpiece. The control device 100 controls an operation of the semiconductor manufacturing apparatus 10 based on preset conditions and acquires various pieces of data obtained during the process from the semiconductor manufacturing apparatus 10 to monitor a state of the semiconductor manufacturing apparatus 10.

Hereinafter, a configuration of the semiconductor manufacturing apparatus 10 will be described assuming that the semiconductor manufacturing apparatus is a plasma processing apparatus. The semiconductor manufacturing apparatus 10 has a cylindrical chamber 11 having an inner portion that may be hermetically sealed. The chamber 11 is made of, for example, aluminum, and is connected to a ground potential. A stage 12 made of a conductive material such as aluminum is provided within the chamber 11. The stage 12 is a cylindrical stage on which a semiconductor wafer W (hereinafter, also simply referred to as a wafer W), which is a workpiece, is disposed. The stage 12 is configured to also function as a lower electrode.

An exhaust path 13 is formed between a side wall of the chamber 11 and a side surface of the stage 12. The exhaust path 13 serves as a path that discharges gases above the stage 12 to the outside of the chamber 11. An exhaust plate 14 is disposed midway along the exhaust path 13. The exhaust plate 14 is a plate-shaped member with a plurality of holes, and functions as a partition plate that divides a space inside the chamber 11 into an upper space and a lower space.

The upper space of the chamber 11 is a reaction chamber 17 where plasma etching is performed, and the lower space of the chamber 11 is an exhaust chamber (manifold) 18. An exhaust pipe 15 is connected to the exhaust chamber 18 to discharge a gas inside the chamber 11. The exhaust plate 14 captures or reflects a plasma generated in the reaction chamber 17 to suppress leakage of the plasma into the exhaust chamber 18. The exhaust pipe 15 is connected to an exhaust device via an adaptive pressure control (APC) valve 16. The exhaust device reduces the pressure inside the chamber 11 and maintains the inside of the chamber 1 in a desired vacuum state.

A first radio-frequency power supply 19 is connected to the stage 12 via a matching unit 20. The first radio-frequency power supply 19 supplies radio-frequency bias power of, for example, 400 kHz to 13.56 MHz to the stage 12. The matching unit 20 suppresses the reflection of radio-frequency power from the stage 12, and maximizes the efficiency of supplying radio-frequency bias power to the stage 12.

An electrostatic chuck 22 including an electrostatic electrode plate 21 inside is disposed on an upper surface of the stage 12. The electrostatic chuck 22 has a shape in which an upper disc-shaped member having a diameter smaller than that of a lower disc-shaped member is disposed on the lower disc-shaped member in an overlapping manner. The electrostatic chuck 22 is made of aluminum, and an upper surface of the electrostatic chuck 22 is thermally sprayed with ceramics. When the wafer W is disposed on the stage 12, the wafer W is disposed on the upper disc-shaped member of the electrostatic chuck 22. A first direct current (DC) power supply 23 is connected to the electrostatic electrode plate 21. The electrostatic chuck 22 generates electrostatic force such as Coulomb force by a voltage applied from the first DC power supply 23 to the electrostatic electrode plate 21, and adsorbs and holds the wafer W by the electrostatic force.

An edge ring 24 having a circular shape is disposed on the electrostatic chuck 22 to surround a circumferential portion of the wafer W. The edge ring 24 is made of a conductive material (e.g., silicon) and converges a plasma toward a surface of the wafer W in the reaction chamber 17, thereby improving the efficiency of an etching process.

A coolant chamber 25 having a circular shape and extending in, for example, a circumferential direction, is provided within the stage 12. A low-temperature coolant is circulated and supplied to the coolant chamber 25 from a chiller unit through a coolant pipe 26. The low-temperature coolant is cooling water or Galden (registered trademark). The stage 12, which has been cooled by the low-temperature coolant, cools the wafer W and the edge ring 24 through the electrostatic chuck 22.

The electrostatic chuck 22 includes a plurality of heat transfer gas supply holes 27. A heat transfer gas such as helium (He) gas is supplied to the plurality of heat transfer gas supply holes 27 through a heat transfer gas supply line 28. The heat transfer gas is supplied to a gap between an adsorption surface of the electrostatic chuck 22 and a back surface of the wafer W through the heat transfer gas supply holes 27. The heat transfer gas supplied to the gap functions to transfer the heat of the wafer W to the electrostatic chuck 22.

A temperature adjustment module may be connected to the stage 12 to adjust at least one of the electrostatic chuck 22 and the wafer W to a target temperature. The temperature adjustment module is configured to include a heat source such as a heater, a heat transfer medium, and a channel for the heat transfer medium, and adjusts at least one of the electrostatic chuck 22 and the wafer W to a target temperature under the control of the control device 100.

A shower head 29 is provided on a ceiling of the chamber 11 to face the stage 12. The shower head 29 includes an upper electrode 33 having a plurality of gas holes 32, a cooling plate 34 to which the upper electrode 33 is detachably assembled, and a lid 35 covering the cooling plate 34. A buffer chamber 36 is provided within the cooling plate 34. A gas introduction pipe 37 is connected to the buffer chamber 36. The shower head 29 diffuses a gas introduced from the gas introduction pipe 37, in the buffer chamber 36, and supplies the diffused gas into the reaction chamber 17 through the plurality of gas holes 32.

A second radio-frequency power supply 31 is connected to the upper electrode 33 via a matching unit 30. The second radio-frequency power supply 31 supplies radio-frequency power for plasma excitation, for example, of about 40 MHz, to the upper electrode 33. The matching unit 30 suppresses reflection of radio-frequency power from the upper electrode 33, and maximizes the efficiency of supplying the radio-frequency power for plasma excitation to the upper electrode 33. In the present embodiment, the radio-frequency power for plasma excitation is applied to the upper electrode 33, but the radio-frequency power for plasma excitation may be applied to the stage 12.

The cooling plate 34 includes a cooling mechanism to cool the upper electrode 33. The cooling mechanism includes a spiral or annular coolant chamber 38 extending in a circumferential direction, and a coolant pipe 38a. A low-temperature coolant is circulated and supplied from a chiller unit to the coolant chamber 38 through the coolant pipe 38a. The low-temperature coolant is cooling water or Galden (registered trademark). The temperature of the upper electrode 33 is increased by heat input from the plasma. Therefore, in the semiconductor manufacturing apparatus 10 according to an embodiment of the present disclosure, the upper electrode 33 and the cooling plate 34 are in close contact with each other, and the heat of the upper electrode 33 is dissipated to the cooling plate 34 to radiate heat from the upper electrode 33, thereby cooling the upper electrode 33.

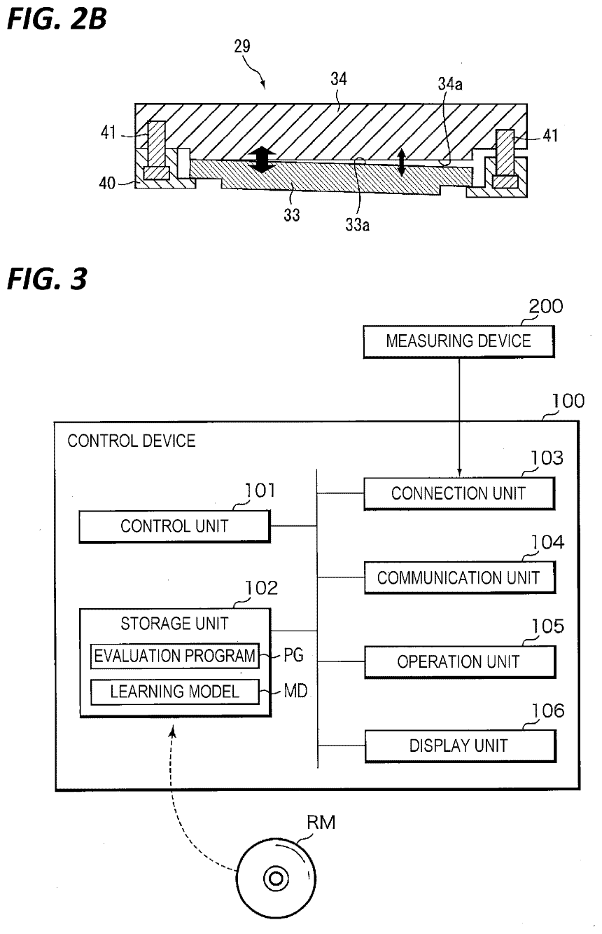

FIGS. 2A and 2B are schematic diagrams illustrating a configuration of main components of the shower head 29. As described above, the shower head 29 includes the upper electrode 33 and the cooling plate 34. The upper electrode 33 is a disc-shaped member made of a conductive material such as silicon. The cooling plate 34 is a disc-shaped member made of a conductive material such as aluminum. In the schematic diagrams of FIGS. 2A and 2B, configurations, such as the gas holes 32 of the upper electrode 33 and the buffer chamber 36 of the cooling plate 34, are omitted for simplification.

The upper electrode 33 is assembled to the cooling plate 34 by using, for example, a clamp member 40 and a screw 41. The clamp member 40 is a circular-shaped member. The clamp member 40 supports a circumferential portion of the upper electrode 33 from the bottom thereof, and is screwed to the cooling plate 34 by the screw 41 in a state where the upper electrode 33 is inserted between the clamp member 40 and the cooling plate 34. As a result, the upper electrode 33 is assembled to the cooling plate 34 in a state where an upper surface 33a thereof is in contact with a lower surface 34a of the cooling plate 34. In the present embodiment, the screw 41 is an example of fastening parts, and a bolt may be used instead of the screw 41.

In the present embodiment, the upper electrode 33 is assembled in contact with the cooling plate 34, but the upper electrode 33 and the cooling plate 34 may be assembled with another member such as a heat transfer sheet or a heater interposed therebetween.

FIG. 2A illustrates a state where no gap is provided between the upper electrode 33 and the cooling plate 34, that is, a state where assembly accuracy is high. In this case, it is considered that heat is conducted uniformly between the upper electrode 33 and the cooling plate 34. In a manufacturing process of the semiconductor wafer W, heat is input to the upper electrode 33 from the plasma generated in the chamber 11, and the heat is dissipated from the upper electrode 33 to the cooling plate 34. However, when the heat is conducted uniformly between the upper electrode 33 and the cooling plate 34, the surface temperature of the upper electrode 33 becomes uniform within the surface thereof. Thus, it is considered that no process abnormality occurs due to non-uniformity in the surface temperature.

Meanwhile, FIG. 2B illustrates a state where a gap is partially generated between the upper electrode 33 and the cooling plate 34, that is, a state where assembly accuracy is low. For example, when some of the screws 41 that screw the clamp members 40 are bent, or when some of the screws 41 are tightened with an incorrect torque, a gap may be partially generated between the upper electrode 33 and the cooling plate 34. Also, when a foreign material is inserted between the upper electrode 33 and the cooling plate 34, or when contamination or roughness is formed on a portion of a contact surface between the two, heat conduction may partially change. In these cases, it is considered that the heat is not conducted uniformly between the upper electrode 33 and the cooling plate 34.

When the surface temperature of the upper electrode 33 becomes non-uniform within the surface thereof, an abnormality may occur in etching rate (ER) or critical dimension (CD) due to the non-uniformity in the surface temperature. Even when a gap of about 1 μm is generated between the upper electrode 33 and the cooling plate 34, process abnormalities such as an ER abnormality and a CD abnormality occur. However, it is difficult to detect the gap of about 1 μm by visual inspection or measurement using a Vernier calliper.

In the related art, after processing the semiconductor wafer W (hereinafter, also simply referred to as the wafer W), the in-plane distribution of the ER or CD, which is the result of processing the wafer W, is checked. Then, when an abnormality such as a bias in the in-plane distribution of the ER or CD is confirmed, the assembly accuracy is determined to be low, and countermeasures such as reassembling the upper electrode 33 are taken. For example, in the related art, it was not possible to evaluate the assembly accuracy before the start of operation. When it was determined that the assembly accuracy was low after the start of operation, it was necessary to reassemble parts. In the present embodiment, “operation” means a processing on the wafer W. For example, in an apparatus that performs plasma processing, “operation” means a state where plasma generation may be performed, including pressure control, gas control, temperature control, and the application of pressure to electrodes for plasma processing. With regard to this, “state before the start of operation” includes the state of an apparatus in an assembly stage before an operation state is prepared.

The control device 100 according to the present embodiment acquires data regarding surface temperature distribution of the upper electrode 33, and evaluates the assembly accuracy of the upper electrode 33 based on the acquired data regarding the surface temperature distribution. An evaluation result is presented to an operator who has performed an assembly work. When the evaluation result indicates that the assembly accuracy is low, the operator may retighten the screws 41 or reassemble the upper electrode 33, thereby improving the assembly accuracy before the start of operation.

In the present embodiment, a description is made assuming that a part to be evaluated for assembly accuracy is the upper electrode 33, but the part to be evaluated is not limited to the upper electrode 33. For example, a method according to the present disclosure may be applied to any part that is assembled in the inside or outside of the chamber 11 of the semiconductor manufacturing apparatus 10 and whose surface temperature distribution may be measured, such as the stage 12, the edge ring 24, a peripheral electrode, and an inner wall of the chamber 11.

FIG. 3 is a block diagram illustrating an internal configuration of the control device 100. The control device 100 is a dedicated or general-purpose computer including, for example, a control unit 101, a storage unit 102, a connection unit 103, a communication unit 104, an operation unit 105, and a display unit 106.

The control unit 101 includes a central processing unit (CPU), a read only memory (ROM), and a random access memory (RAM). The ROM included in the control unit 101 stores control programs that control an operation of each hardware unit included in the control device 100. The CPU in the control unit 101 reads and executes the control programs stored in the ROM and various computer programs stored in the storage unit 102, and controls the operation of each hardware unit, thereby causing the entire apparatus to function as an evaluation apparatus of the present disclosure. The RAM included in the control unit 101 temporarily stores data used during the execution of computation.

In the present embodiment, the control unit 101 is configured to include the CPU, the ROM, and the RAM, but the configuration of the control unit 101 is not limited to those described above. The control unit 101 may be, for example, one or more control circuits or arithmetic circuits including, for example, a graphic processing unit (GPU), a field programmable gate array (FPGA), a digital signal processor (DSP), a quantum processor, and a volatile or non-volatile memory. The control unit 101 may include functions such as a clock for outputting date and time information, a timer for measuring the time elapsed from the time when a measurement start instruction is applied to the time when a measurement end instruction is applied, and a counter for counting the number.

The storage unit 102 includes storages such as a hard disk drive (HDD), a solid state drive (SSD), and an electronically erasable programmable read only memory (EEPROM). Various computer programs executed by the control unit 101 and various types of data used by the control unit 101 are stored in the storage unit 102.

The computer program (program product) stored in the storage unit 102 includes an evaluation program PG for evaluating the assembly accuracy of a part (upper electrode 33 in the present embodiment) that is assembled in the semiconductor manufacturing apparatus 10 based on the surface temperature distribution of the part. The evaluation program PG may be a single computer program or may be configured with a plurality of computer programs. Furthermore, these computer programs may partially use an existing library.

The computer program including the evaluation program PG is provided by a non-transitory recording medium RM on which the computer program is recorded in a readable manner. The recording medium RM is a portable memory such as a CD-ROM, a USB memory, a secure digital (SD) card, a micro-SD card, or a compact flash (registered trademark). The control unit 101 reads various types of computer programs from the recording medium RM using a reading device (not illustrated) and stores the read various types of computer programs in the storage unit 102. The computer program stored in the storage unit 102 may be provided through communication. In this case, the control unit 101 may acquire the computer program through communication by the communication unit 104, and store the acquired computer program in the storage unit 102.

A learning model MD is stored in the storage unit 102. The learning model MD performs learning for detecting an abnormality in the data of temperature distribution input from the connection unit 103. In the present embodiment, it is assumed that a trained learning model MD is stored in the storage unit 102. For example, the storage unit 102 stores therein constituent information of layers constituting the learning model MD, information of nodes constituting each layer, and a model parameter such as a weighting or bias between nodes. The configuration of the learning model MD will be described in detail later.

A measuring device 200 is connected to the connection unit 103 to measure the surface temperature distribution of the upper electrode 33. Any measuring device 200 may be used as long as it may measure the surface temperature distribution of the upper electrode 33. In an embodiment, the measuring device 200 is an infrared camera that measures radiant heat from a surface of the upper electrode 33. When the infrared camera is used, the surface (lower surface) of the upper electrode 33 is pre-coated with a film such as carbon, CF, SiN, SiO₂, or metal, and the temperature thereof is measured in a pre-coated state. The pre-coated film may be removed in situ before starting a mass production process of the semiconductor wafers W.

In another embodiment, the measurement device 200 is a wafer-type temperature sensor. The wafer-type temperature sensor may be a sensor for measuring radiant heat from the upper electrode 33, or a sensor that comes into contact with the lower surface of the upper electrode 33 to measure the surface temperature thereof.

A temperature measurement probe may be attached to a transport arm (not illustrated) for transporting the semiconductor wafer W, and the surface of the upper electrode 33 may be scanned to measure the surface temperature distribution.

The surface temperature distribution of the upper electrode 33 may be measured by attaching a plurality of thermocouples to the P-Pin and contacting the thermocouples with the surface of the upper electrode 33.

The surface temperature of the upper electrode 33 may be measured, by coating the surface of the upper electrode 33 with a material whose color changes when heated, such as a thermochromic material or cholesteric liquid crystal, and then, observing the change in color. The coated material may be removed in-situ before starting the mass production process of the semiconductor wafers W.

The communication unit 104 includes a communication interface for transmitting and receiving various types of data to and from an external device. As for the communication interface of the communication unit 104, a communication interface that complies with a communication standard, such as LAN (Local Area Network), may be used. The external device may include the semiconductor manufacturing apparatus 10 and a server device (not illustrated). When data to be transmitted is input from the control unit 101, the communication unit 104 transmits the data to a receiver's external device. When data transmitted from the external device is received, the communication unit 104 outputs the received data to the control unit 101.

The operation unit 105 includes operation devices such as a touch panel, a keyboard, and a switch, and accepts various operations and settings by an operator. The control unit 101 performs appropriate control based on various types of operation information provided by the operation unit 105, and stores setting information in the storage unit 102 as needed.

The display unit 106 includes a display device such as a liquid crystal monitor or an organic electroluminescence (EL) display, and displays information to be notified to the operator, in response to an instruction from the control unit 101.

The control device 100 in the present embodiment may be a single computer, or may be a computer system including a plurality of computers or peripheral devices. In addition, the control device 100 may be a virtual machine whose entity is virtualized, or may be a cloud. In the present embodiment, the control device 100 and the semiconductor manufacturing apparatus 10 are described as separate components, but the control device 100 may be a computer provided within the semiconductor manufacturing apparatus 10.

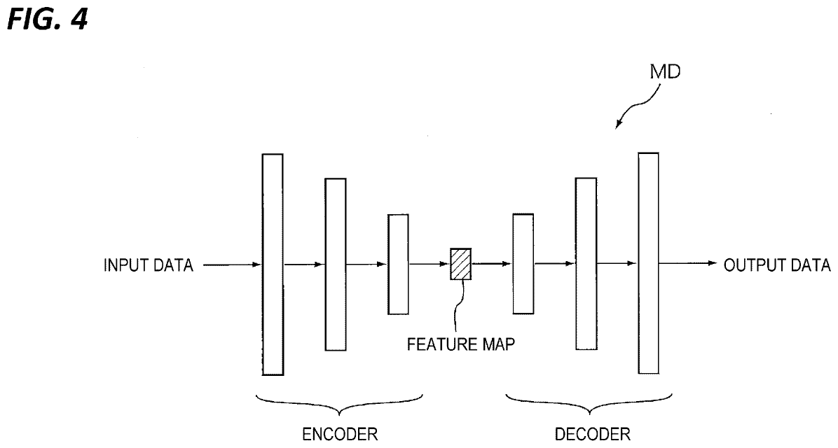

FIG. 4 is a schematic diagram illustrating a configuration of the learning model MD. The learning model MD is, for example, an auto-encoder, and is configured by a neural network including an encoder and a decoder. The encoder performs dimensional compression (downsampling) on input data through one or more intermediate layers thereof that perform a convolution product, and extracts a feature map. In the present embodiment, as for the input data, for example, image data (e.g., a heat map) representing the surface temperature distribution of the upper electrode 33 at a specific timing may be used. The decoder performs reconstruction (upsampling) of the data through the one or more intermediate layers from the feature map, and outputs reconstructed data as output data.

The learning model MD is generated by performing machine learning using only normal images as training data. In the present embodiment, the normal image is an image representing surface temperature distribution obtained when the upper electrode 33 is normally assembled to the cooling plate 34. The model parameter such as a weighting or bias between nodes, which is derived by machine learning is stored in the storage unit 102. The machine learning for generating the learning model MD may be performed within the control device 100 or may be performed in an external server device. In the latter case, a trained learning model MD may be downloaded from the server device, and the downloaded trained learning model MD may be stored in the storage unit 102.

The learning model MD is trained using only normal images as training data. Thus, when normal data is input to the learning model MD, the encoder may extract the feature of the normal data, and the decoder may restore original data based on the feature of the normal data. Meanwhile, when data including an abnormality (data including an abnormal portion) is input to the learning model MD, the encoder may not extract the feature of the data including the abnormality, and the decoder may not restore an original image. Using this, the control unit 101 of the control device 100 may calculate the degree of abnormality of input data by calculating an error between input data to the learning model MD and output data obtained from the learning model MD. A method of calculating the degree of abnormality may be appropriately designed. For example, a difference in pixel value for each pixel may be calculated, and the sum of the squares of the difference in each pixel value may be calculated as the degree of abnormality. When it is determined that the calculated degree of abnormality is less than a set value, the control unit 101 determines the input data to be normal. When it is determined that the calculated degree of abnormality is equal to or greater than the set value, the control unit 101 determines the input data to be abnormal.

In the present embodiment, the learning model MD using the auto-encoder has been described. However, any suitable learning model used for abnormality detection, such as a variational autoencoder (VAE), a deep one-class classification (DOC), a structural similarity index measure (SSIM) auto-encoder, a generative adversarial network (GAN) or EfficientNet, may be used.

In the present embodiment, the learning model MD trained using the surface temperature distribution at a certain timing has been described. However, the learning model MD may be constructed using changes in surface temperature over time during increasing or decreasing the temperature (e.g., changes in average temperature of the entire surface over time) as training data. Since it is considered that a difference is generated between a temperature change when the assembly accuracy is high and a temperature change when the assembly accuracy is low, machine learning is performed using data (e.g., a graph) regarding the temperature change when the assembly accuracy is high as correct data, thereby constructing a learning model that detects the temperature change when the assembly accuracy is low as an abnormality.

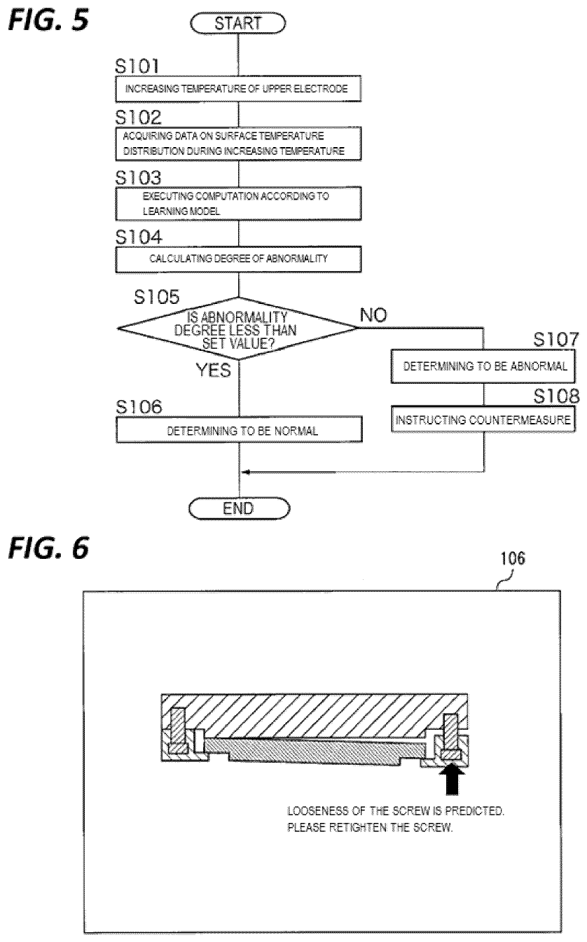

FIG. 5 is a flowchart explaining a sequence of processing steps performed by the control device 100. After the upper electrode 33 is assembled to the cooling plate 34, and the semiconductor manufacturing apparatus 10 is completed as a product, the control unit 101 reads out the evaluation program PG from the storage unit 102 and executes the evaluation program PG to perform the following process.

The control unit 101 controls an operation of the temperature adjustment module, for example, to increase the temperature of the upper electrode 33 (step S101). The temperature adjustment module for the upper electrode 33 includes a heat source such as a heater, a heat transfer medium, and a channel for the heat transfer medium and is configured to increase the temperature of the upper electrode 33 under the control of the control unit 101. While the temperature of the upper electrode 33 is being increased by the temperature adjustment module, heat is input from the temperature adjustment module to the upper electrode 33 and the heat is dissipated from the upper electrode 33 to the cooling plate 34. The control unit 101 may drive the radio-frequency power supplies 19 and 31 to generate a plasma in the chamber 11, and increase the temperature of the upper electrode 33 using the generated plasma.

The control unit 101 acquires data regarding the surface temperature distribution measured by the measuring device 200 while the temperature of the upper electrode 33 is being increased, through the connection unit 103 (step S102). In the present embodiment, image data (heat map) representing the surface temperature distribution of the upper electrode 33 at a specific timing during the increasing of the temperature is acquired as data of the surface temperature distribution. The image data representing the surface temperature distribution may be generated in the measuring device 200 or in the control unit 101.

The control unit 101 inputs the acquired data of the surface temperature distribution into the learning model MD and executes computation by the learning model MD (step S103).

The control unit 101 calculates the error between the input data to the learning model MD and the output data obtained from the learning model MD, and calculates the degree of abnormality of the input data based on the calculated error (step S104). For example, the control unit 101 may calculate the difference in pixel value for each pixel and calculate the sum of squares of the difference in each pixel value as the degree of abnormality.

The control unit 101 compares the calculated degree of abnormality with a set value set in advance and determines whether the calculated degree of abnormality is less than the set value (step S105). When the calculated degree of abnormality is less than the set value (step S105: YES), the control unit 101 determines that the surface temperature distribution of the upper electrode 33 is uniform (normal) (step S106). In this case, the control unit 101 may evaluate that the assembly accuracy of the upper electrode 33 to the cooling plate 34 is high. Based on an evaluation result, the control unit 101 may allow the display unit 106 to display information that the assembly accuracy of the upper electrode 33 is high or information that it is possible to start the mass production of the semiconductor wafers W. In addition, when the surface of the upper electrode 33 is coated, the control unit 101 may perform an etching process for removing the coating in the chamber 11.

When the calculated degree of abnormality is equal to or greater than the set value (step S105: NO), the control unit 101 determines that the surface temperature distribution of the upper electrode 33 is not uniform (abnormal) (step S107). In this case, the control unit 101 evaluates that the assembly accuracy of the upper electrode 33 to the cooling plate 34 is low.

When the control unit 101 evaluates that the surface temperature distribution of the upper electrode 33 is not uniform (abnormal) and that the assembly accuracy of the upper electrode 33 to the cooling plate 34 is low, the control unit 101 instructs an operator to take a countermeasure (step S108). For example, the control unit 101 displays a plurality of countermeasures including retightening of the screws 41 and reassembling of the upper electrode 33, as selection choices on the display unit 106. Alternatively, the control unit 101 may display preset countermeasures on the display unit 106.

The control unit 101 may detect a location where an assembly defect has occurred and output information regarding the detected location of the assembly defect. The control unit 101 may detect a location where an assembly defect has occurred, by calculating a difference in each pixel value between the input data to the learning model MD and the output data obtained from the learning model MD and scanning obtained difference data. Here, the scanning of the difference data means inspecting the difference data over an entire region of the upper electrode 33. The control unit 101 sequentially executes processes of determining whether the difference data has a maximum or minimum along an inspection line in a specific direction while shifting the inspection line in a direction intersecting the specific direction, and determines whether the maximum or minimum exists or not over the entire region of the upper electrode 33. When there exists a location where the difference data has the maximum or minimum, the control unit 101 determines that the location of the assembly defect has been detected, and displays, for example, information regarding the detected location as image or text information on the display unit 106.

In addition, the control unit 101 may accumulate case information that associates the location of the assembly defect with a countermeasure previously taken in the storage unit 102. When the location of the assembly defect is specified, the control unit 101 may read out corresponding case information from the storage unit 102 and present the corresponding case information to an operator as a countermeasure.

Furthermore, the control unit 101 may detect an occurrence pattern of the assembly defect and output information regarding countermeasures according to the detected occurrence pattern. Here, the control unit 101 distinguishes and detects an assembly defect accompanied by a pinpoint temperature abnormality (first occurrence pattern) and an assembly defect accompanied by a gradual temperature distribution (second occurrence pattern), as the detected pattern of the assembly defect. The control unit 101 may detect the occurrence pattern of the assembly defect by checking the surface temperature distribution of the upper electrode 33. For example, as described above, the control unit 101 may calculate the difference in each pixel value between the input data to the learning model MD and the output data obtained from the learning model MD, and may check the surface temperature distribution of the upper electrode 33 depending on whether obtained difference data includes a maximum or minimum. When the difference data includes the maximum or minimum, the control unit 101 determines that the assembly defect accompanied by a pinpoint temperature abnormality (first occurrence pattern) has been detected. In this case, since it is considered that a foreign material has been caught, the control unit 101 may instruct the operator to reassemble the upper electrode 33 as a countermeasure. Furthermore, when the pinpoint temperature abnormality is detected in the vicinity of a specific screw 41, the control unit 101 may instruct the operator to retighten the specific screw 41 as a countermeasure. Meanwhile, when the difference data does not include the maximum and a minimum, the control unit 101 determines that an assembly defect accompanied by a gradual temperature distribution (second occurrence pattern) has been detected. In this case, since it is considered that the assembly defect of the upper electrode 33 has occurred, the control unit 101 may instruct the operator to reassemble the upper electrode 33 as a countermeasure.

In the present embodiment, the display unit 106 of the control device 100 is configured to display a location where an abnormality has occurred and a countermeasure, but control may be performed to display the location and the countermeasure on a mobile terminal carried by an operator, or on augmented reality (AR) glasses worn by the operator.

In addition, when it is determined that the surface temperature distribution is ununiform (abnormal) in step S107, the control unit 101 may output an alarm and stop an operation of the entire apparatus.

FIG. 6 is a schematic diagram illustrating an example of a display when an abnormality is detected. Based on the acquired surface temperature distribution, for example, when it is detected that the surface temperature in the vicinity of the screw on the right of FIG. 6 is lower than the surface temperature of a surrounding area thereof, the control unit 101 may estimate that the screw is loose or that a foreign material is trapped nearby. In this case, the control unit 101 may display on the display unit 106 that the screw on the right may be loose and that the screw on the right needs to be retightened, as illustrated in FIG. 6, and instruct the operator to take a countermeasure. Alternatively, the control unit 101 may instruct the operator to reassemble the upper electrode 33, since there is a possibility that a foreign material is caught between the upper electrode 33 and the cooling plate 34.

In the flowchart of FIG. 5, a configuration of acquiring data regarding the surface temperature distribution during the increasing of the temperature is provided, but a configuration of acquiring data regarding the surface temperature distribution during the decreasing of the temperature may be provided. The control unit 101 may decrease the temperature of the upper electrode 33 by stopping the generation of the plasma and cooling the cooling plate 34 with a cooling mechanism. Since the upper electrode 33 is made of a material with high thermal conductivity such as silicon, the surface temperature thereof is rapidly uniformized. However, by using data regarding the surface temperature distribution during the increasing or decreasing of the temperature, temperature changes within the surface of the upper electrode 33 may be detected with high accuracy. In addition, detection accuracy may be improved by repeatedly increasing and decreasing the temperature of the upper electrode 33 and using data regarding the surface temperature distribution obtained by the repeated increasing and decreasing of the temperature.

In the present embodiment, the assembly accuracy of the upper electrode 33 is evaluated based on the surface temperature distribution of the upper electrode 33. However, in addition to the surface temperature distribution, at least one of pieces of data including a current value, a reflected wave power, a particle number, a yield, a process result, electrical impedance, ultrasonic detection, a gap of the upper electrode, a position of the upper electrode, distortion of the upper electrode, a gas flow rate, a pressure, and an image in the semiconductor manufacturing apparatus 10 may be acquired, and the acquired data may be analyzed to evaluate the assembly accuracy. For example, a learning model such as an auto-encoder may be constructed based on data when a part including the upper electrode 33 is normally assembled, and newly acquired data may be input into the learning model to detect whether an abnormality exists or not in the data, and the assembly accuracy may be evaluated based on a detection result.

In the present embodiment, an application example of the semiconductor manufacturing apparatus 10 is described by taking the plasma processing apparatus as an example, but the present disclosure is not limited to the semiconductor manufacturing apparatus 10 and may be applied to any substrate processing apparatus in which a part equipped with a heat source or a part whose temperature is controlled through a member having a heat source is assembled. For example, the present disclosure may be applied to semiconductor manufacturing apparatuses such as an exposure apparatus, an etching apparatus, a film formation apparatus, an ion implantation apparatus, an ashing apparatus, a sputtering apparatus, and a substrate transport unit, or flat panel display manufacturing apparatuses.

According to the present disclosure, assembly accuracy may be evaluated at a stage before operation starts.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An evaluation apparatus comprising:
acquisition circuitry configured to acquire data regarding surface temperature distribution of a part that is assembled in a substrate processing apparatus; and
evaluation circuitry configured to evaluate an assembly accuracy of the part based on the acquired data regarding the surface temperature distribution of the part.

2. The evaluation apparatus according to claim 1, wherein the part is a part equipped with a heat source, or a part whose temperature is controlled through a member including a heat source.

3. The evaluation apparatus according to claim 1, wherein the part includes at least one of an upper electrode, a peripheral electrode, a stage, an edge ring, and an inner wall of a processing chamber.

4. The evaluation apparatus according to claim 1, wherein the evaluation circuitry are configured to evaluate the assembly accuracy of the part based on the data regarding the surface temperature distribution while the temperature of the part is being increased or decreased.

5. The evaluation apparatus according to claim 1, wherein the evaluation circuitry are configured to evaluate the assembly accuracy using a learning model that has learned a feature amount of the surface temperature distribution when the part is normally assembled.

6. The evaluation apparatus according to claim 5, wherein the evaluation circuitry are configured to:
input the data regarding the surface temperature distribution acquired by the acquisition circuitry to the learning model,
compare the data input to the learning model with data obtained from the learning model, thereby detecting a location where an assembly defect occurs, and
output information regarding a detected location when the location where the assembly defect occurs is detected.

7. The evaluation apparatus according to claim 5, wherein the evaluation circuitry are configured to:
input the data regarding the surface temperature distribution acquired by the acquisition unit to the learning model,
compare the data input to the learning model with data obtained from the learning model, thereby detecting an occurrence pattern of an assembly defect and
output information to urge reassembling of the part or retightening of a fastening part according to the detected occurrence pattern.

8. The evaluation apparatus according to claim 1, wherein the acquisition circuitry are configured to acquire at least one of pieces of data including a current value, a reflected wave power, a particle number, a yield, a process result, electrical impedance, ultrasonic detection, a gap of an upper electrode, a position of the upper electrode, distortion of the upper electrode, a gas flow rate, a pressure, and an image in the substrate processing apparatus, and
the evaluation circuitry are configured to evaluate the assembly accuracy of the part based on the at least one piece of data acquired from the acquisition circuitry and the data regarding the surface temperature distribution.

9. An evaluation method executed by a computer, the method comprising:
acquiring data regarding surface temperature distribution of a part that is assembled in a substrate processing apparatus, and
evaluating an assembly accuracy of the part based on the acquired data regarding the surface temperature distribution of the part.

10. The evaluation method according to claim 9, wherein the part is a part equipped with a heat source, or a part whose temperature is controlled through a member including a heat source, and
the evaluating of the assembly accuracy of the part is executed by the computer, based on the data regarding the surface temperature distribution while a temperature of the part is being increased or decreased.

11. The evaluation method according to claim 9, wherein a surface of the part is coated with a coating, and
after evaluating the assembly accuracy of the part, the coating is removed by the substrate processing apparatus.

12. A non-transitory computer-readable storage medium having stored therein a computer program that causes a computer to execute a process including:
acquiring data regarding surface temperature distribution of a part that is assembled in a substrate processing apparatus; and
evaluating an assembly accuracy of the part based on the acquired data regarding the surface temperature distribution of the part.
